(19) United States
(12) Patent Application Publication
(10) Pub. No.: US 2025/0046359 A1
(43) Pub. Date: Feb. 6, 2025

(54) Controlling Usage-Based Disturbance Mitigation

(71) Applicant: Micron Technology, Inc., Boise, ID (US)

(72) Inventors: Yang Lu, Boise, ID (US); Mark Kalei Hadrick, Boise, ID (US); Donald Morgan, Boise, ID (US)

(73) Assignee: Micron Technology, Inc., Boise, ID (US)

(21) Appl. No.: 18/742,634

(22) Filed: Jun. 13, 2024

Related U.S. Application Data
(60) Provisional application No. 63/517,293, filed on Aug. 2, 2023.

(51) Int. Cl. G11C 11/406; G11C 11/4076; G11C 11/4096

(52) U.S. Cl. CPC G11C 11/40611; G11C 11/40618; G11C 11/4076; G11C 11/4096

(57) ABSTRACT

Apparatuses and techniques for controlling usage-based disturbance mitigation are described. In an example aspect, usage-based disturbance mitigation is performed between activation and precharging of a row. More specifically, usage-based disturbance circuitry performs an array counter update procedure while the row is active. The techniques for controlling usage-based disturbance mitigation control timing of the array counter update procedure at a multi-bank level or a local-bank level. Additionally, the techniques for controlling usage-based disturbance mitigation control a timing of a precharging operation to ensure completion of the array counter update procedure. The techniques for controlling usage-based disturbance mitigation are not limited to the array counter update procedure and can generally be applied to other aspects of usage-based disturbance mitigation, such as bit-error detection and/or correction.

### CROSS-REFERENCE TO RELATED APPLICATION(S)

This application claims the benefit of U.S. Provisional Patent Application Ser. No. 63/517,293 filed on Aug. 2, 2023, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for controlling usage-based disturbance mitigation are described with reference to the following drawings. The same numbers are used throughout the drawings to reference like features and components:

FIG. 1 illustrates example apparatuses that can implement aspects of controlling usage-based disturbance mitigation;

FIG. 2 illustrates an example computing system that can implement aspects of controlling usage-based disturbance mitigation;

FIG. 3 illustrates an example memory device in which aspects of controlling usage-based disturbance mitigation may be implemented;

FIG. 4 illustrates an example arrangement of a multi-bank control circuit and local bank control circuits on a die;

FIG. 5 illustrates example components of control circuitry capable controlling usage-based disturbance mitigation;

FIG. 6 illustrates example operands of a mode register for controlling timing associated with usage-based disturbance mitigation;

FIG. 7-1 illustrates an example multi-bank control circuit capable of controlling usage-based disturbance mitigation;

FIG. 7-2 illustrates an example timing diagram for controlling usage-based disturbance mitigation using a multi-bank control circuit;

FIG. 8-1 illustrates an example local bank control circuit capable of controlling usage-based disturbance mitigation;

FIG. 8-2 illustrates an example timing diagram for controlling usage-based disturbance mitigation using a local bank control circuit;

FIG. 9 illustrates a first example method of a memory device performing aspects of controlling usage-based disturbance mitigation;

FIG. 10 illustrates a second example method of a memory device performing aspects of controlling usage-based disturbance mitigation; and

FIG. 11 illustrates a third example method of a memory device performing aspects of controlling usage-based disturbance mitigation.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

To meet the demands for physically smaller memories, memory devices can be designed with higher chip densities. Increasing chip density, however, can increase the electromagnetic coupling (e.g., capacitive coupling) between adjacent or proximate rows of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1”. In this example, the voltage fluctuation can cause a sense amplifier to incorrectly determine the state of the memory cell to be a “0” instead of a “1”. Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an R^{th} row are subjected to repeated activation, which causes one or more memory cells in an adjacent row (e.g., within an R+1 row, an R+2 row, an R−1 row, and/or an R−2 row) to change states. This effect is referred to as usage-based disturbance. The occurrence of usage-based disturbance can lead to the corruption or changing of contents within the affected row of memory.

To address this and other issues regarding usage-based disturbance, this document describes techniques for controlling usage-based disturbance mitigation. One aspect of usage-based disturbance mitigation involves keeping track of how often a row is activated since a last refresh. More specifically, usage-based disturbance circuitry performs an array counter update procedure, which updates an activation count associated with an activated row. The activation count is stored within a subset of memory cells within the activated row. To limit an impact to overall system timing, execution of the array counter update procedure is constrained to a time frame in which the row is active for normal memory operations, such as a normal read operation or a normal write operation. In other words, the usage-based disturbance mitigation is performed between activation and precharging of the row.

The techniques for controlling usage-based disturbance mitigation control timing of the array counter update procedure at a multi-bank level or a local-bank level. Additionally, the techniques for controlling usage-based disturbance mitigation control a timing of a precharging operation to ensure completion of the array counter update procedure. The techniques for controlling usage-based disturbance mitigation are not limited to the array counter update procedure and can generally be applied to other aspects of usage-based disturbance mitigation, such as bit-error detection and/or correction.

### Example Operating Environments

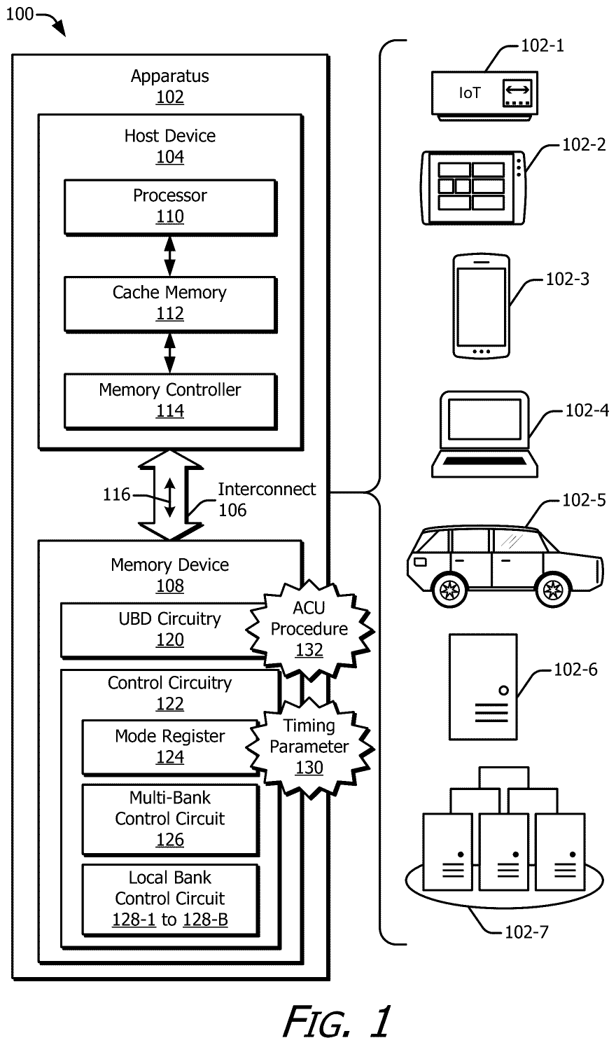

FIG. 1 illustrates, at 100 generally, an example operating environment including an apparatus 102 that can implement aspects of controlling usage-based disturbance mitigation. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes at least one instance of usage-based disturbance circuitry 120 and at least one instance of control circuitry 122.

The usage-based disturbance circuitry 120 mitigates usage-based disturbance for one or more banks associated with the memory device 108. The usage-based disturbance circuitry 120 can be implemented using software, firmware, hardware, fixed circuit circuitry, or combinations thereof. The usage-based disturbance circuitry 120 can also include at least one counter circuit for updating an activation count and/or at least one error-correction-code (ECC) circuit for detecting and/or correcting bit errors.

The control circuitry 122 can include various components that the memory device 108 can use to perform various operations, such as communicating with other devices, managing memory performance, performing refresh operations (e.g., self-refresh operations or auto-refresh operations, and supporting usage-based disturbance mitigation. The control circuitry 122 includes at least one mode register 124, at least one multi-bank control circuit 126 (e.g., a bank-group control circuit), and local bank control circuits 128-1 to 128-B, where B represents a positive integer.

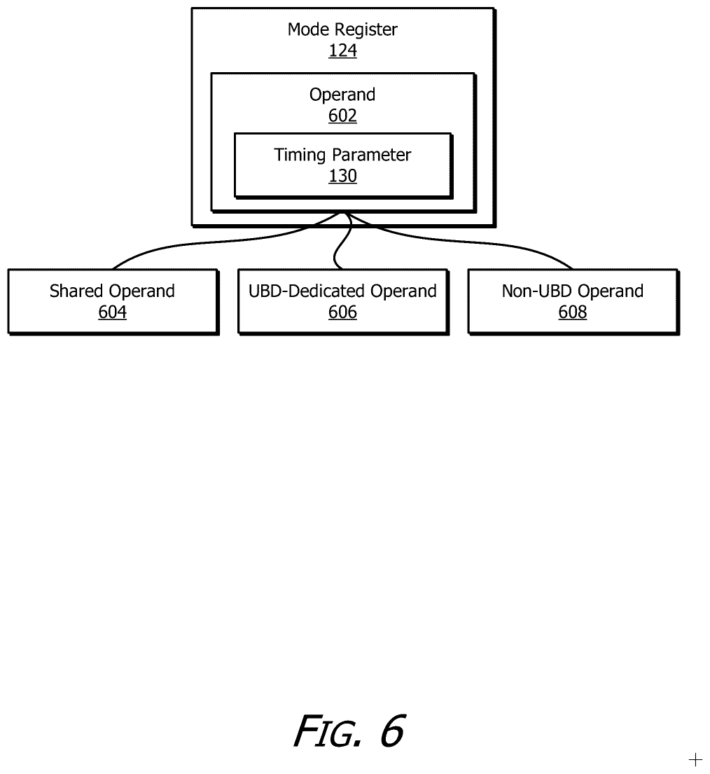

The mode register 124 stores a timing parameter 130. The control circuitry 122 references the timing parameter 130 to determine when to initiate an operation associated with usage-based disturbance mitigation and/or when to initiate precharging of an activated row. The information associated with the timing parameter 130 can be represented in a variety of different manners, as further described with respect to FIG. 6.

The multi-bank control circuit 126 generates internal commands for multiple banks (e.g., multiple banks of a bank group) based on external commands received from the memory controller 114 via the interconnect 106. In this manner, the multi-bank control circuit 126 can control the operations of multiple banks within the memory device 108. The multi-bank control circuit 126 can be implemented using software, firmware, hardware, fixed circuit circuitry, or combinations thereof.

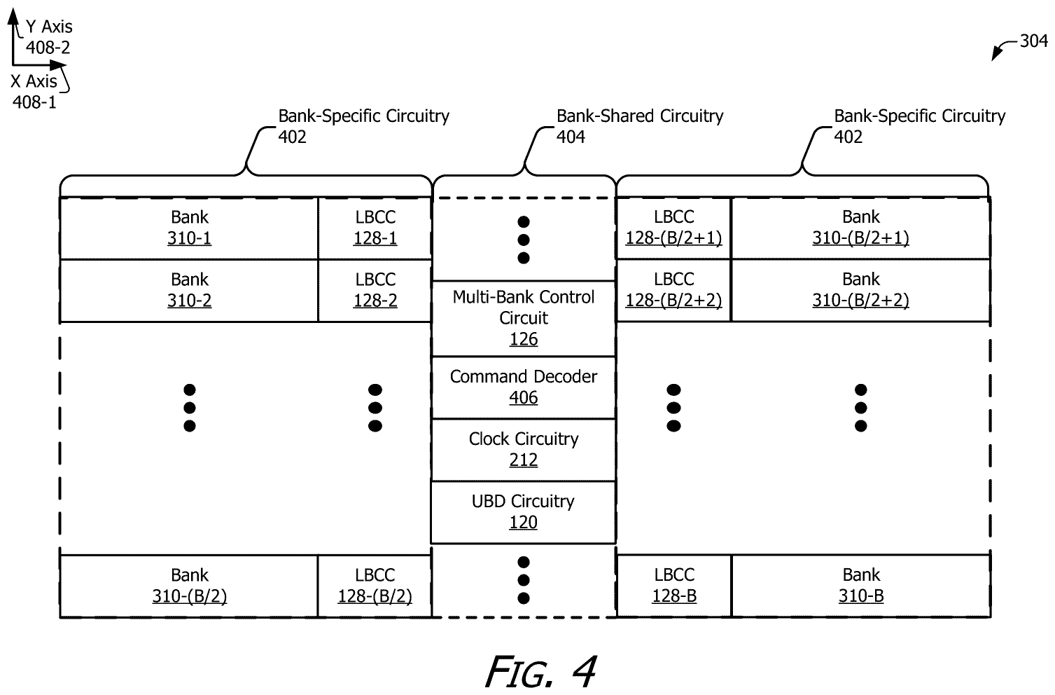

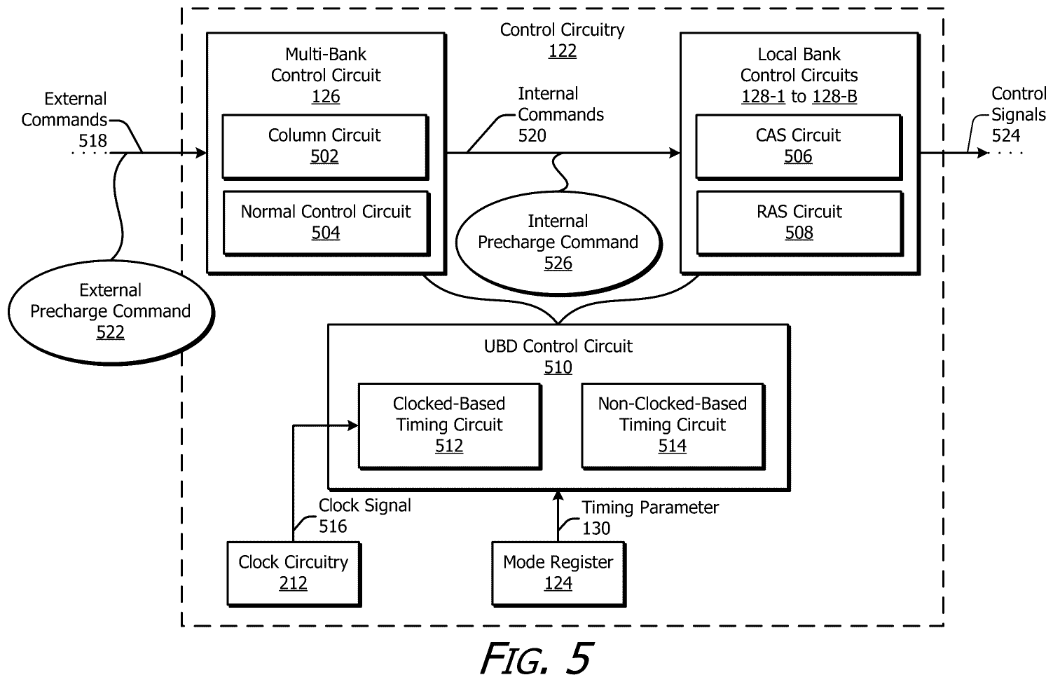

Each local bank control circuit 128-1 to 128-B controls an operation of its corresponding bank based on the internal commands received from the multi-bank control circuit 126. The local bank control circuits 128-1 to 128-B can be implemented using software, firmware, hardware, fixed circuit circuitry, or combinations thereof. An example layout and example components of the multi-bank control circuit 126 and the local bank control circuits 128-1 to 128-B are further described with respect to FIGS. 4 and 5.

Generally speaking, the techniques for controlling usage-based disturbance mitigation can be performed, at least partially, by the control circuitry 122. More specifically, these techniques can be implemented at a multi-bank level using the multi-bank control circuit 126 or can be implemented at a local-bank level using the local bank control circuits 128-1 to 128-B.

One controllable aspect of usage-based disturbance mitigation involves an array counter update procedure 132 (ACU procedure 132). The usage-based disturbance circuitry 120 performs the array counter update procedure 132 to update an activation count associated with an activated row. To update the activation count, the usage-based disturbance circuitry 120 reads the activation count that is stored within the activated row, increments the activation count, and writes the updated activation count to the activated row. By maintaining the activation count, the usage-based disturbance circuitry 120 can determine when to perform a refresh operation to reduce the risk of usage-based disturbance.

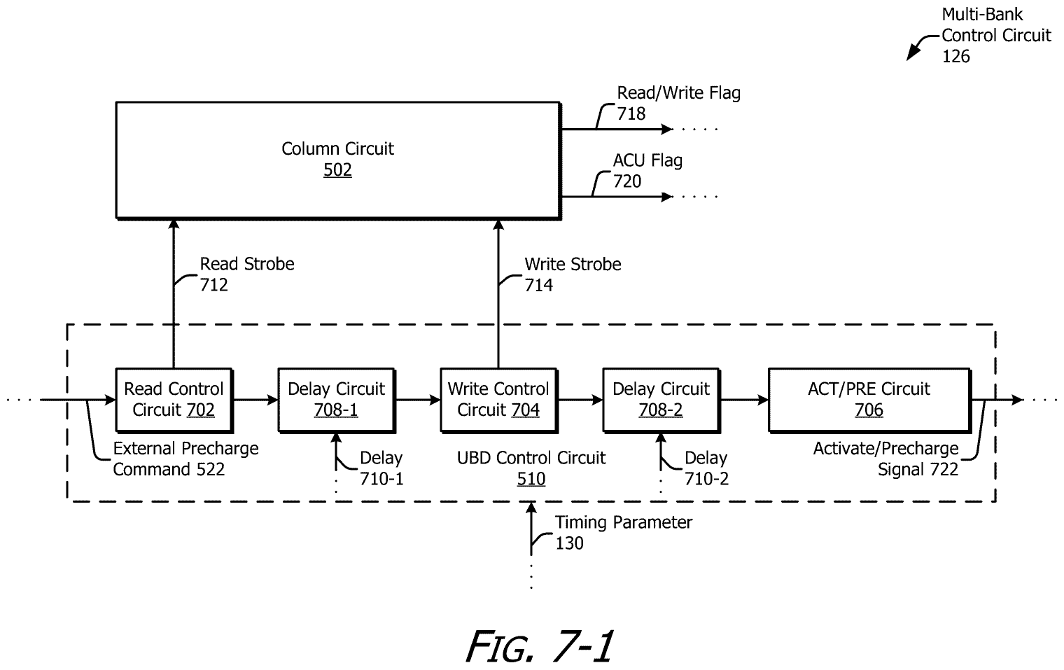

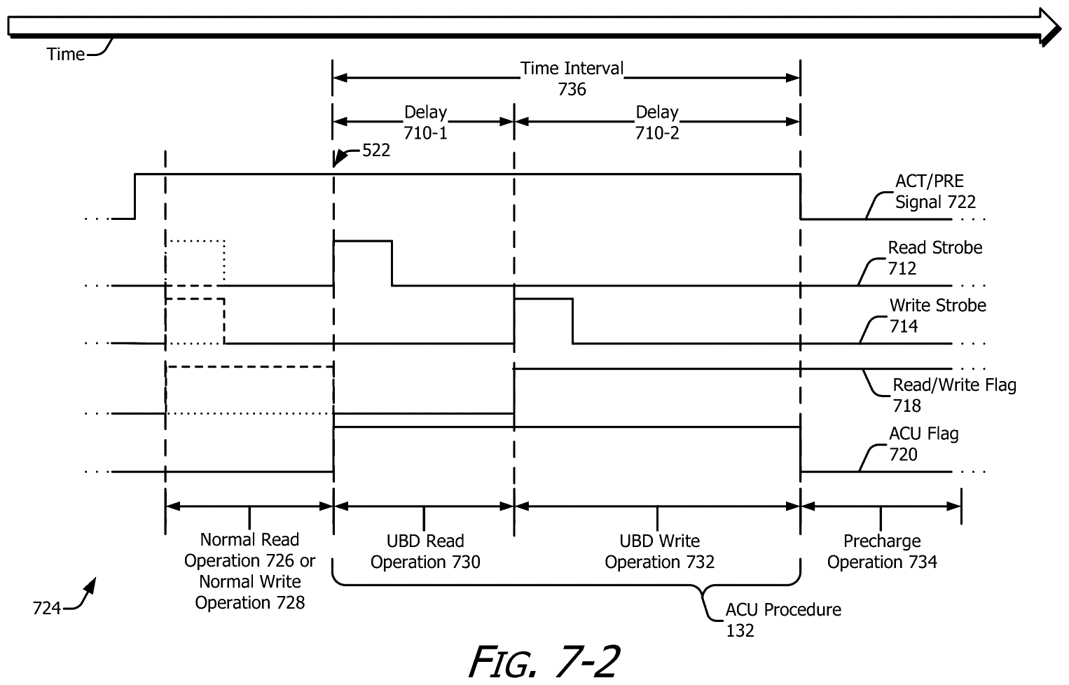

In a first example implementation, the multi-bank control circuit 126 generates internal commands to initiate and execute one or more operations associated with the array counter update procedure 132. Additionally, the multi-bank control circuit 126 can control a timing of a precharge operation to ensure completion of the array counter update procedure 132. An example implementation of the multi-bank control circuit 126 controlling usage-based disturbance mitigation is further described with respect to FIG. 7-1.

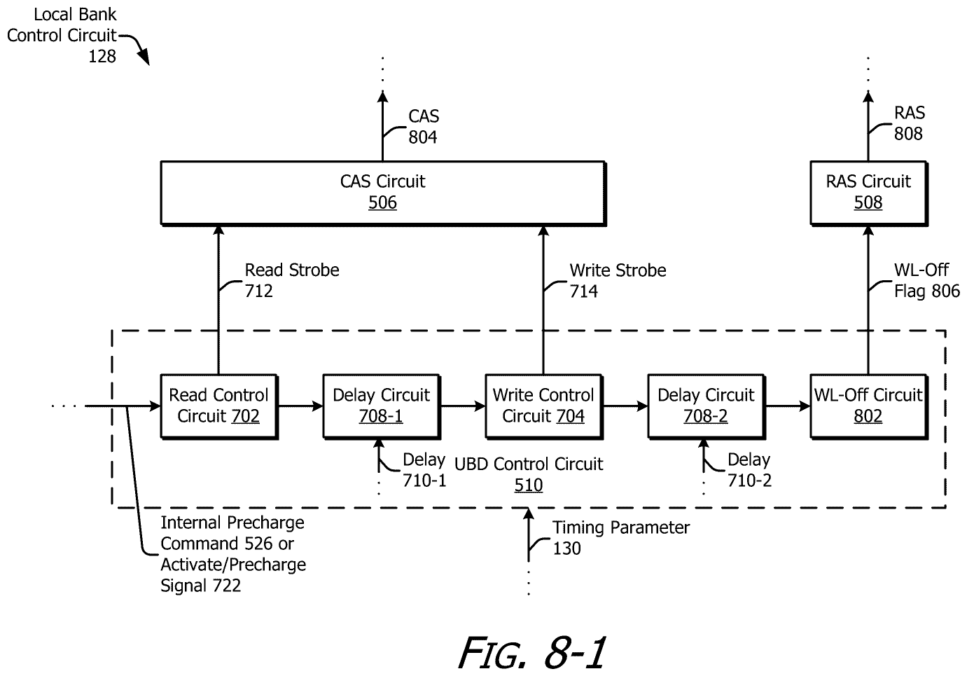

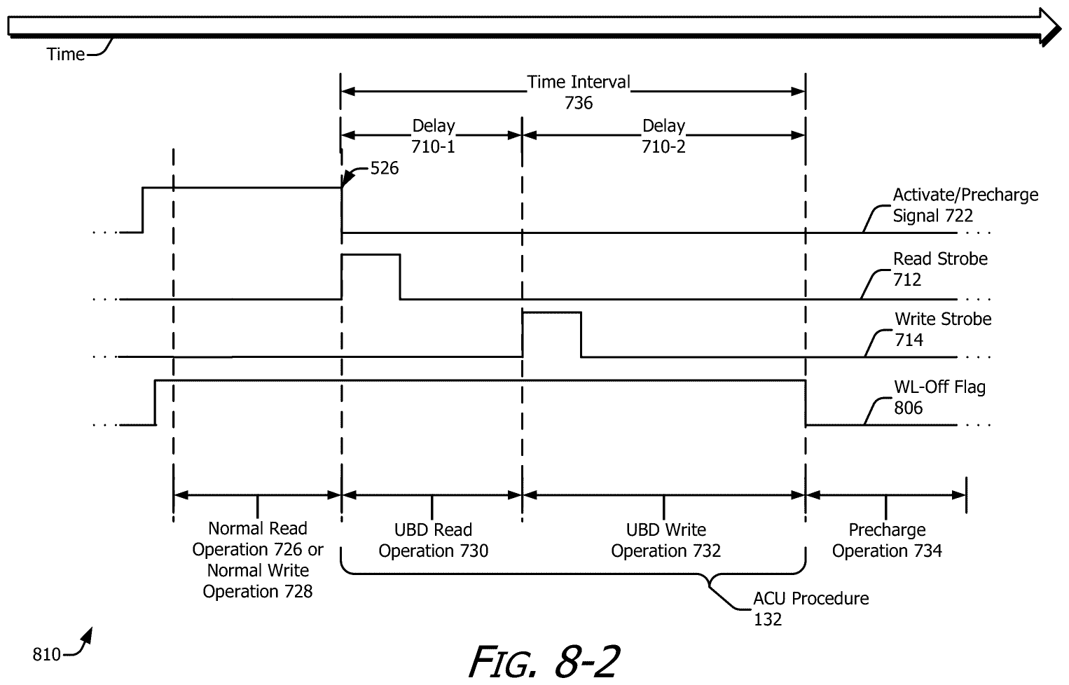

In a second example implementation, the local bank control circuits 128-1 to 128-B generate signals to initiate and execute one or more operations associated with the array counter update procedure 132. The local bank control circuits 128-1 to 128-B can initiate the array counter update procedure 132 based on an internal command (e.g., an internal precharge command) generated by the multi-bank control circuit 126. Additionally, the local bank control circuits 128-1 to 128-B can control a timing of a precharge operation to ensure completion of the array counter update procedure 132. An example implementation of the local bank control circuit 128 controlling usage-based disturbance mitigation is further described with respect to FIG. 8-1.

In general, execution of the array counter update procedure 132 takes time and the row has to be active during the array counter update procedure 132. This means that the precharging of the activated row is delayed based on a duration of the array counter update procedure 132. It is therefore desirable for the control circuitry 122 to control timing of the array counter update procedure 132 and control timing of the precharging operation in a reliable and efficient manner to constrain an amount of time the memory device 108 requires between receiving an external precharge command and a next external activate command.

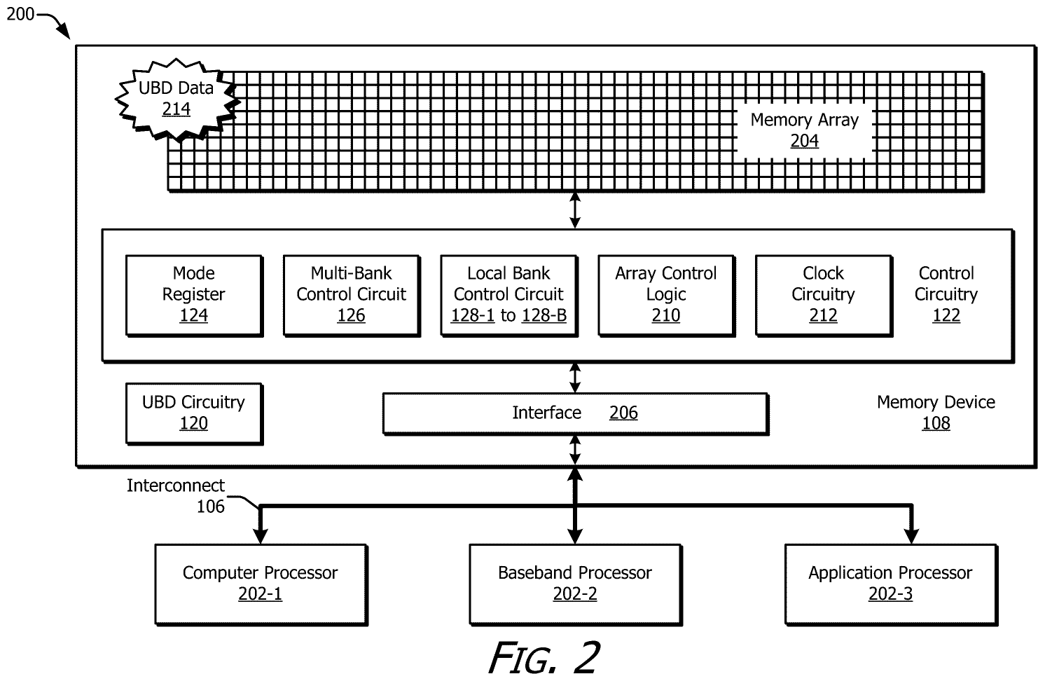

Although the techniques for controlling usage-based disturbance mitigation are described with respect to the array counter update procedure 132, these techniques can generally be applied for initiating and performing any type of operation that enables the usage-based disturbance circuitry 120 to mitigate usage-based disturbance. Other operations can include bit-error detection and/or correction using the usage-based disturbance circuitry 120. The control circuitry 122 is further described with respect to FIG. 2.

FIG. 2 illustrates an example computing system 200 that can implement aspects of controlling usage-based disturbance mitigation. In some implementations, the computing system 200 includes at least one memory device 108, at least one interconnect 106, and at least one processor 202. The memory device 108 can include, or be associated with, at least one memory array 204, at least one interface 206, and the control circuitry 122 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 122 may be components on a single semiconductor die or on separate semiconductor dies. The memory array 204 or the control circuitry 122 may also be distributed across multiple dies. This control circuitry 122 may manage traffic on a bus that is separate from the interconnect 106.

In the depicted configuration, the control circuitry 208 includes the mode register 124, the multi-bank control circuit 126, the local bank control circuits 128-1 to 128-B, at least one instance of array control circuit 210, and at least one instance of clock circuitry 212. The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

The memory device 108 also includes the usage-based disturbance circuitry 120. In some aspects, the usage-based disturbance circuitry 120 can be considered part of the control circuitry 122. For example, the usage-based disturbance circuitry 120 can represent another part of the control circuitry 122. The usage-based disturbance circuitry 120 can be coupled to a set of memory cells within the memory array 204 that store usage-based disturbance data 214. The usage-based disturbance data 214 can include information such as an activation count, which represents a quantity of times one or more rows within the memory array 204 have been activated (or accessed) by the memory device 108.

In example implementations, each row of the memory array 204 includes a subset of memory cells that stores the usage-based disturbance data 214 associated with that row. For example, a first row includes a subset of memory cells that store a first activation count representing a quantity of times the first row has been activated. Additionally, a second row includes another subset of memory cells that store a second activation count representing a quantity of times the second row has been activated. Other implementations are also possible in which the activation count represents a quantity of activations associated with more than one row.

The interface 206 can couple the control circuitry 122 or the memory array 204 directly or indirectly to the interconnect 106. In some implementations, the usage-based disturbance circuitry 120, the mode register 124, the multi-bank control circuit 126, the local bank control circuits 128-1 to 128-B, the array control circuit 210, and the clock circuitry 212 can be part of a single component (e.g., the control circuitry 122). In other implementations, one or more of the usage-based disturbance circuitry 120, the mode register 124, the multi-bank control circuit 126, the local bank control circuits 128-1 to 128-B, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices).

### Example Techniques and Hardware

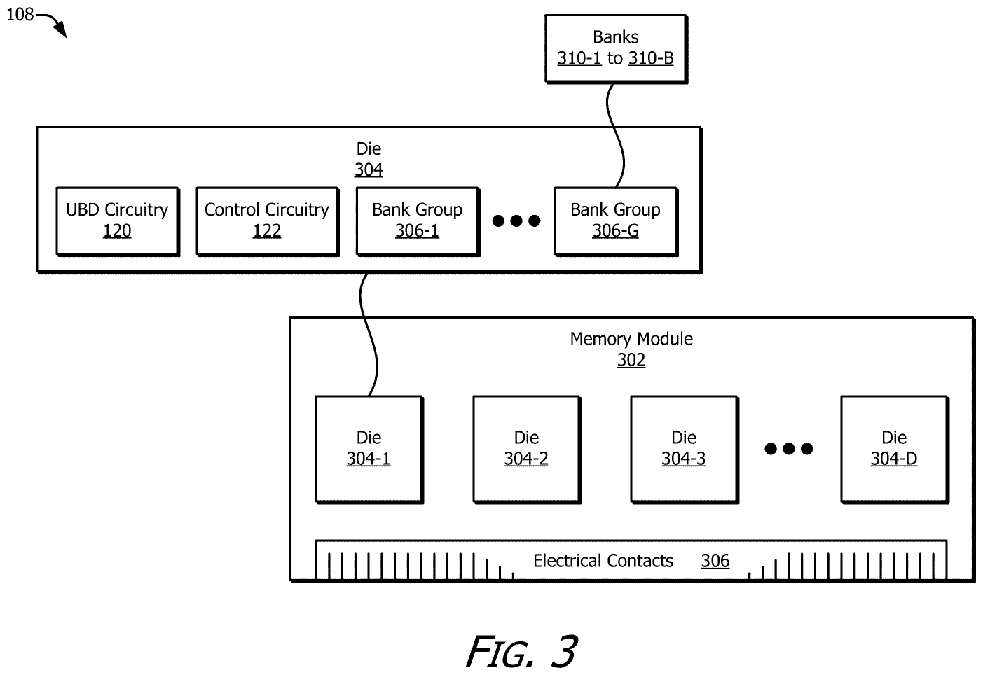

FIG. 3 illustrates an example memory device 108 in which aspects of controlling usage-based disturbance mitigation can be implemented. The memory device 108 includes a memory module 302, which can include multiple dies 304. As illustrated, the memory module 302 includes a first die 304-1, a second die 304-2, a third die 304-3, and a Dth die 304-D, with D representing a positive integer. The memory module 302 can be a SIMM or a DIMM. As another example, the memory module 302 can interface with other components via a bus interconnect (e.g., a Peripheral Component Interconnect Express (PCIc®) bus). The memory device 108 illustrated in FIGS. 1 and 2 can correspond, for example, to multiple dies (or dice) 304-1 through 304-D, or a memory module 302 with two or more dies 304. As shown, the memory module 302 can include one or more electrical contacts 306 (e.g., pins) to interface the memory module 302 to other components.

The memory module 302 can be implemented in various manners. For example, the memory module 302 may include a printed circuit board, and the multiple dies 304-1 through 304-D may be mounted or otherwise attached to the printed circuit board. The dies 304 (e.g., memory dies) may be arranged in a line or along two or more dimensions (e.g., forming a grid or array). The dies 304 may have a similar size or may have different sizes. Each die 304 may be similar to another die 304 or different in size, shape, data capacity, or control circuitries. The dies 304 may also be positioned on a single side or on multiple sides of the memory module 302.

One or more of the dies 304-1 to 304-D includes the usage-based disturbance circuitry 120, the control circuitry 122, and bank groups 308-1 to 308-G, with G representing a positive integer. Each bank group 308 includes at least two banks 310, such as banks 310-1 to 310-B. In some implementations, the die 304 includes multiple instances of the usage-based disturbance circuitry 120, which mitigate usage-based disturbance across at least one of the banks 310. For example, multiple instances of the usage-based disturbance circuitry 120 can respectively mitigate usage-based disturbance across the bank groups 308-1 to 308-G. In this example, one instance of usage-based disturbance circuitry 120 mitigates usage-based disturbance across multiple banks 310-1 to 310-B of a bank group 308. In another example, multiple instances of the usage-based disturbance circuitry 120 can respectively mitigate usage-based disturbance for respective banks 310. In this case, each usage-based disturbance circuitry 120 mitigates usage-based disturbance for a single bank 310 within one of the bank groups 308-1 to 306-B. In yet another example, each usage-based disturbance circuitry 120 mitigates usage-based disturbance for a subset of the banks 310 associated with one of the bank groups 308-1 to 308-G, where the subset of the banks 310 includes at least two banks 310. The relationship between the banks 310-1 to 310-B and the control circuitry 122 are further described with respect to FIG. 4.

FIG. 4 illustrates an example arrangement of the multi-bank control circuit 126 and local bank control circuits 128-1 to 128-B (LBCC 128-1 to 128-B) on a die 304. The dic 304 includes bank-specific circuitry 402 and bank-shared circuitry 404. Bank-specific circuitry 402 includes components that are associated with a particular bank 310. For example, the bank-specific circuitry 402 includes the banks 310-1, 310-2 . . . 310-(B/2), 310-(B/2+1), 310-(B/2+2) . . . 310-B and the local bank control circuits 128-1, 128-2 . . . 128-(B/2), 128-(B/2+1), 128-(B/2+2) . . . 128-B. The local bank control circuits 128-1 to 128-B are respectively coupled to the banks 310-1 to 310-B. In some cases, subsets of the banks 310-1 to 310-B are associated with different bank groups 308. In an example implementation, the dic 304 includes 32 banks 310 (e.g., B equals 32). The 32 banks 310 form eight bank groups 308 (e.g., G equals 8), with each bank group 308 including four of the banks 310. In other cases, the banks 310-1 to 310-B are associated with a single bank group 308.

The bank-shared circuitry 404 includes components that are associated with multiple banks 310. These components perform operations associated with multiple banks 310. Example components of the bank-shared circuitry 404 include the multi-bank control circuit 126, a command decoder 406 of the array control circuit 210, and the clock circuitry 212. In this example, the usage-based disturbance circuitry 120 is shown as part of the bank-shared circuitry 404. Alternatively, multiple instances of the usage-based disturbance circuitry 120 can be implemented as part of the bank-specific circuitry 402.

In an example implementation, the multi-bank control circuit 126 is positioned proximate to (or integrated within) the command decoder 406. In some cases, a distance between the multi-bank control circuit 126 and the command decoder 406 is shorter than a distance between the multi-bank control circuit 126 and one of the banks 310.

On the die 304, the bank-specific circuitry 402 is positioned on two opposite sides of the bank-shared circuitry 404. Explained another way, the bank-shared circuitry 404 can be centrally positioned on the die 304. As such, the multi-bank control circuit 126 can be positioned closer to a center of the die 304 compared to the edges of the dic 304. Positioning the bank-shared circuitry 404 in the center enables routing between the bank-shared circuitry 404 and the bank-specific circuitry 402 to be simplified.

Consider a first axis 408-1 (e.g., X axis 408-1) and a second axis 408-2 (e.g., Y axis 408-2), which is perpendicular to the first axis 408-1. In FIG. 4, the first axis 408-1 is depicted as a “horizontal” axis, and the second axis 408-2 is depicted as a “vertical” axis. Components of the bank-shared circuitry 404 are distributed across the second axis 408-2. A first set of the banks (e.g., banks 310-1 to 310-B/2) are arranged along the second axis 408-2 on a “left” side of the bank-shared circuitry 404, and a second set of the banks (e.g., banks 310-(B/2+1) to 310-B) are arranged along the second axis 408-2 on a “right” side of the bank-shared circuitry 404. The local bank control circuits 128-1 to 128-B are positioned between the corresponding banks 310-1 to 310-B and the bank-shared circuitry 404. By positioning the multi-bank control circuit 126 in a central location between the local bank control circuits 128-1 to 128-B, it can be easier to route signals between the multi-bank control circuit 126 and the local bank control circuits 128-1 to 128-B.

As described in more detail with respect to FIG. 5, the multi-bank control circuit 126 or the local bank control circuits 128-1 to 128-B can perform aspects of controlling usage-based disturbance mitigation. In a first implementation, the multi-bank control circuit 126 provides this control without significantly increasing the die size. However, additional routing is necessary to pass control signals from the multi-bank control circuit 126 to the local bank control circuits 128-1 to 128-B. In a second implementation, the local bank control circuits 128-1 to 128-B provides this control without changing the signal routing between the multi-bank control circuit 126 and the local bank control circuits 128-1 to 128-B. This is because the local bank control circuits 128-1 to 128-B can perform aspects of controlling usage-based disturbance mitigation based on a signal that is already provided by the multi-bank control circuit 126. Utilizing the local bank control circuits 128-1 to 128-B to implement aspects of controlling usage-based disturbance mitigation, however, can require additional space. As such, the die 304 can have a larger footprint in this second implementation compared to the first implementation.

In some cases, the techniques for controlling usage-based disturbance mitigation can be performed based on a clock signal generated by the clock circuitry 212. In this case, it can be easier to have the multi-bank control circuit 126 control the usage-based disturbance mitigation because the multi-bank control circuit 126 is positioned proximate to the clock circuitry 212. This close proximity can mitigate delays associated with passing the clock signal from the clock circuitry 212 to the multi-bank control circuit 126. In comparison, it can be more challenging to perform aspects of controlling usage-based disturbance mitigation based on the clock signal using the local bank control circuits 128-1 to 128-B due to the additional signal routing between the clock circuitry 212 and the local bank control circuits 128-1 to 128-B. In this case, variations in delay may require additional timing margins, which can make it challenging to perform aspects of usage-based disturbance mitigation within an available time interval. The control circuitry 122 is further described with respect to FIG. 5.

FIG. 5 illustrates example components of the control circuitry 122 for controlling usage-based disturbance mitigation. In the depicted configuration, the control circuitry 122 includes the mode register 124, the multi-bank control circuit 126, the local-bank control circuits 128-1 to 128-B, and the clock circuitry 212. The multi-bank control circuit 126 is coupled to the local bank control circuits 128-1 to 128-B. The multi-bank control circuit 126 includes a column circuit 502 (or column logic) and a normal control circuit 504. The column circuit 502 generates commands for initiating and/or executing various operations of the memory device 108. The normal control circuit 504 controls a timing of these commands for initiating and executing a normal read operation or a normal write operation. The multi-bank control circuit 126 controls the operation of the local bank control circuits 128-1 to 128-B.

The local bank control circuits 128-1 to 128-B are respectively coupled to the banks 310-1 to 310-B (not shown) and respectively control operations of the banks 310-1 to 310-B. Each one of the local bank control circuits 128-1 to 128-B includes column address strobe (CAS) circuit 506 (CAS circuit 506) (or column address strobe logic) and row address strobe (RAS) circuit 508 (RAS circuit 508) (or row address strobe logic). Operations of the column address strobe circuit 506 and the row address strobe circuit 508 are further described with respect to FIG. 8-1.

The control circuitry 122 also includes a usage-based-disturbance control circuit 510 (UBD control circuit 510), which can be implemented within the multi-bank control circuit 126 (as shown in FIG. 7-1) or each of the local bank control circuits 128-1 to 128-B (as shown in FIG. 8-1). If the usage-based-disturbance control circuit 510 is implemented as part of the multi-bank control circuit 126, the normal control circuit 504 and the usage-based-disturbance control circuit 510 can utilize at least some of the same components. The usage-based-disturbance control circuit 510 controls a timing associated with the array counter update procedure 132 and a precharging operation. In particular, the usage-based-disturbance control circuit 510 initiates the array counter update procedure 132 and initiates precharging after an appropriate amount of time has passed to ensure that the array counter update procedure 132 completed.

Implementing the usage-based-disturbance control circuit 510 within the multi-bank control circuit 126 (e.g., at the multi-bank level) can have a smaller impact on a footprint of the memory device 108 but increase the cost and complexity associated with routing signals between the multi-bank control circuit 126 and the local bank control circuits 128-1 to 128-B. Alternatively, implementing the usage-based-disturbance control circuit 510 within the local bank control circuits 128-1 to 128-B (e.g., at the local bank level) can have a smaller impact on signal routing between the multi-bank control circuit 126 and the local bank control circuits 128-1 to 128-B at the cost of increasing a footprint of the memory device 108.

The usage-based-disturbance control circuit 510 is coupled to the mode register 124. The mode register 124 stores at least one timing parameter 130. The usage-based-disturbance control circuit 510 reads or accesses the timing parameter 130 from the mode register 124 to determine an amount of time associated with performing one or more aspects of the array counter update procedure 132. In an example implementation, the timing parameter 130 includes a time interval that specifies a time between reading of the activation count as part of the array counter update procedure 132 and the precharging operation. In general, the usage-based-disturbance control circuit 510 can initiate (or trigger) the precharging operation based on the timing parameter 130.

The usage-based-disturbance control circuit 510 can be implemented using a clock-based timing circuit 512 or a non-clocked-based timing circuit 514. The clock-based timing circuit 512 is coupled to the clock circuitry 212 and evaluates the passage of time based on a clock signal 516. The non-clock-based timing circuit 514 evaluates the passage of time based on another timing aspect or mechanism that is independent of the clock signal 516. The non-clock-based timing circuit 514 can be implemented using an analog delay, such as a gate delay circuit or a resistor-capacitor delay circuit.

During an operation, the multi-bank control circuit 126 receives external commands 518 from the memory controller 114 (not shown). In some implementations, the command decoder 406 (not shown) decodes and passes the decoded external commands 518 to the multi-bank control circuit 126. The column circuit 502 generates internal commands 520 based on the external commands 518. For normal operations, such as a normal read operation or a normal write operation, the normal control circuit 504 controls a timing of the internal commands 520. The normal control circuit 504 can control the timing of the internal commands 520 for situations in which the external command 518 is an external activate command, an external read command, or an external write command. For usage-based-disturbance, the usage-based-disturbance control circuit 510 controls a timing of the internal commands 520. The usage-based-disturbance control circuit 510 can control the timing of the internal commands 520 for situations in which the external command 518 is an external precharge command 522.

The local bank control circuits 128-1 to 128-B generate control signals 524 based on the internal commands 520. The control signals 524 cause the banks 310 to perform an operation associated with the internal command 520. If the usage-based-disturbance control circuit 510 is implemented within the local bank control circuits 128-1 to 128-B, the usage-based-disturbance control circuit 510 can control a timing of the control signals 524 for situations in which the internal commands 520 include an internal precharge command 526. The mode register 124 is further described with respect to FIG. 6.

FIG. 6 illustrates an example mode register 124 for controlling timing associated with usage-based disturbance mitigation. The mode register 124 stores the timing parameter 130 within at least one operand 602. The operand 602 can represent a shared operand 604, a usage-based-disturbance-dedicated operand 606 (UBD-dedicated operand 606), or a non-usage-based-disturbance operand 608 (non-UBD operand 608). For the shared operand 604 and the usage-based-disturbance-dedicated operand 606, the timing parameter 130 can represent a time interval during which the array counter update procedure 132 is performed. The time interval can be specified in terms of a quantity of clock cycles or in units of time (e.g., in nanoseconds). For the non-usage-based-disturbance operand 608, the timing parameter 130 can represent a parameter that can used to determine the time interval during which the array counter update procedure 132 is performed. In some examples, the time interval for performing the array counter update procedure 132 is equal to 20 nanoseconds (ns). Other values of the time interval are also possible.

The shared operand 604 specifies both the timing parameter 130 and another parameter associated with a memory operation. Explained another way, the shared operand 604 has multiple functions or multiple meanings, one of which is associated with the timing parameter 130. In this case, a value of the operand 602 can be a code that represents a particular value of the timing parameter 130 and a particular value of the other parameter. Consider an example in which the mode register 124 represents mode register 6 (MR6), and the shared operand 604 represents OP[3:0]. In this case, the shared operand 604 specifies both the timing parameter 130 and the write recovery time (nWR or tWR).

In this example, a value of the timing parameter 130 can be equal to a value of the write recovery time multiplied by a factor. Consider a case in which the factor is equal to two thirds. In this case, a first value of the shared operand 604 that represents a write recovery time of 48 clock cycles also represents a timing parameter 130 of 32 clock cycles. A second value of the shared operand 604 that represents a write recovery time of 90 clock cycles also represents a timing parameter 130 of 60 clock cycles. The shared operand 604 enables more efficient use of the mode register 124 at the cost of limiting control of the timing parameter 130.

In contrast to the shared operand 604, the usage-based-disturbance-dedicated operand 606 specifies the timing parameter 130 and does not specify another parameter associated with memory operations. Explained another way, the usage-based-disturbance-dedicated operand 606 has a single function or a single meaning, which is associated with the timing parameter 130. Values of the usage-based-disturbance-dedicated operand 606 can be coded to represent different values of the timing parameter 130. For example, a first value of the usage-based-disturbance-dedicated operand 606 can represent a timing parameter 130 of 32 clock cycles. A second value of the usage-based-disturbance-dedicated operand 606 can represent a timing parameter 130 of 60 clock cycles. The usage-based-disturbance-dedicated operand 606 provides more flexibility for setting the timing parameter 130 compared to the shared operand 604 at the cost of dedicating an operand for usage-based-disturbance mitigation.

Alternatively, the operand 602 can be implemented as a non-usage-based-disturbance operand 608. In this case, the timing parameter 130 can represent a speed (e.g., a clock frequency) utilized by the host device 104. For example, the mode register 124 can be mode register 13 (MR13), and the non-usage-based-disturbance operand 608 can be OP[3:0]. Based on the clock speed indicated by MR13 OP[3:0], the usage-based-disturbance control circuit 510 determines a quantity of clock cycles for performing the array counter update procedure 132 for a predetermined amount of time (e.g., 20 ns). An example implementation of the usage-based-disturbance control circuit 510 at the multi-bank level is further described with respect to FIG. 7-1.

FIG. 7-1 illustrates an example multi-bank control circuit 126 capable of controlling usage-based disturbance mitigation. In the depicted configuration, the multi-bank control circuit 126 is shown to include the column circuit 502 and the usage-based-disturbance control circuit 510. Although not explicitly shown, the column circuit 502 is coupled to the column address strobe circuit 506 of the local bank control circuits 128-1 to 128-B. The usage-based-disturbance control circuit 510 includes a read control circuit 702 (or read control logic), a write control circuit 704 (or write control logic), and an activate/precharge circuit 706 (ACT/PRE circuit 706). The activate/precharge circuit 706 is coupled to the row address strobe circuit 508 of the local bank control circuits 128-1 to 128-B. The usage-based-disturbance control circuit 510 also includes delay circuits 708-1 and 708-2. The first delay circuit 708-1 is coupled between the read control circuit 702 and the write control circuit 704. The second delay circuit 708-2 is coupled between the write control circuit 704 and the activate/precharge circuit 706. The normal control circuit 504 is not shown in FIG. 7-1 for simplicity. In some implementations, the read control circuit 702, the write control circuit 704, and the activate/precharge circuit 706 can be shared between the normal control circuit 504 and the usage-based-disturbance control circuit 510.

In this example, the usage-based-disturbance control circuit 510 has a single signal path in which the read control circuit 702, the first delay circuit 708-1, the write control circuit 704, the delay circuit 708-2, and the activate/precharge circuit 706 are coupled together in series. Other implementations are also possible. For example, the second delay circuit 708-2 can be coupled between the read control circuit 702 and the activate/precharge circuit 706.

For the array counter update procedure 132, the read control circuit 702 initiates reading of the activation count. The write control circuit 704 initiates writing of the updated activation count. The activate/precharge circuit 706 controls a timing associated with the precharging operation. The delay circuit 708-1 ensures that a sufficient amount of time has elapsed for the reading of the activation count to complete before the writing of the updated activation count. The delay circuit 708-2 ensures that a sufficient amount of time has elapsed for the writing of the updated activation count to complete before initiating the precharging operation.

In some implementations, the first delay 710-1 is substantially smaller than the second delay 710-2. Consider a case in which a time interval for performing the array counter update procedure 132 is 20 ns. In this case, the first delay 710-1 can be approximately 5 ns, and the second delay 710-2 can be approximately 15 ns.

The activate/precharge circuit 706 controls the activation and precharging of a row. In this example, the activate/precharge circuit 706 is shown as a single entity for simplicity. Alternatively, the activate/precharge circuit 706 can be implemented using multiple entities. In this case, one of the entities can control the activation of a row and the another one of the entities can control the precharging of a row.

During operation, the usage-based-disturbance control circuit 510 reads the timing parameter 130 from the mode register 124. In one aspect, the usage-based-disturbance control circuit 510 determines first and second delays 710-1 and 710-2 based on the timing parameter 130. In another aspect, the timing parameter 130 directly specifies the first and second delays 710-1 and 710-2. The usage-based-disturbance control circuit 510 receives the external precharge command 522 from the memory controller 114. The external precharge command 522 causes the read control circuit 702 to generate a read strobe 712, which is passed to the column circuit 502. The read control circuit 702 also initiates the delay circuit 708-1. After a first amount of time has elapsed in accordance with the first delay 710-1, the first delay circuit 708-1 triggers the write control circuit 704. The write control circuit 704 generates a write strobe 714, which is passed to the column circuit 502. The write control circuit 704 also initiates the second delay circuit 708-2.

During this time, the column circuit 502 generates a read/write flag 718 and an array-counter-update flag 720, which are based on the read strobe 712 and the write strobe 714. The read/write flag 718 causes the local bank control circuit 128 to perform a read operation or a write operation. The array-counter-update flag 720 causes the read/write flag 718 to be utilized for the array counter update procedure 132. In particular, the array-counter-update flag 720 causes the column address strobe circuit 506 to activate the columns that store the activation count for the activated row. Also, the array-counter-update flag 720 and the read/write flag 718 cause the local bank control circuit 128 to initiate reading of the activation count from the activated row and/or initiate writing of the updated activation count to the activated row.

After a second amount of time has elapsed in accordance with the second delay 710-2, the second delay circuit 708-2 triggers the activate/precharge circuit 706. The activate/precharge circuit 706 generates an activate/precharge signal 722. The activate/precharge signal 722 initiates an activate operation and/or a precharge operation.

Implementing the usage-based-disturbance control circuit 510 within the multi-bank control circuit 126 means that at least three signals are passed from the multi-bank control circuit 126 to each of the local bank control circuits 128-1 to 128-B. These signals include the read/write flag 718, the array counter update flag 720, and the activate/precharge signal 722. A timing associated with these signals is further described with respect to FIG. 7-2.

FIG. 7-2 illustrates an example timing diagram 724 for controlling usage-based disturbance mitigation using the multi-bank control circuit 126. For simplicity, a rising or falling edge of a signal is shown to occur on the dashed line. It is to be understood that there can be an additional delay associated with one or more of these edges that is not explicitly shown in FIG. 7-2.

In the timing diagram 724, the signals represent binary or logic signals. In particular, these signals can have a high voltage, which may be approximately equal to a supply voltage, or a low voltage, which can be approximately equal to a reference voltage. In the example described below, the activate/precharge signal 722 has a low voltage to enable precharging or a high voltage to enable activation. The read/write flag 718 can have a low voltage to enable a read operation or a high voltage to enable a write operation. The array counter update flag 720 can have a low voltage to disable the array counter update procedure 132 or a high voltage to enable that the array counter update procedure 132.

In this example, the memory device 108 performs a normal read operation 726 or a normal write operation 728. Aspects of the normal read operation 726 are represented using a dotted line. Aspects of the normal write operation 728 are represented using a dashed line.

After the normal read operation 726 or the normal write operation 728, the memory device 108 performs the array counter update procedure 132. The array counter update procedure 132 includes a usage-based-disturbance read operation 730 and a usage-based-disturbance write operation 732. A duration of the array counter update procedure 132 is represented by a time interval 736. The time interval 736 represents a summation of the delays 710-1 and 710-2. In some examples, the read/write flag 718 and the array counter update flag 720 cause the column address strobe circuit 506 to generate a column address strobe, such as column address strobe 804 in FIG. 8, for the usage-based-disturbance read operation 730 and/or the usage-based-disturbance write operation 732. After the array counter update procedure 132, the memory device 108 performs a precharge operation 734.

Prior to the normal read operation 726 or the normal write operation 728, the multi-bank control circuit 126 initiates activation of a row by driving the activate/precharge signal 722 from low to high. The activate/precharge circuit 706 keeps driving the activate/precharge signal 722 high for a duration of the normal read operation 726, the normal write operation 728, and the array counter update procedure 132. In a first example, the normal control circuit 504 initiates the normal read operation 726 by driving the read strobe 712 high and driving the write strobe 714 low. This causes the column circuit 502 to drive the read/write flag 718 low and drive the array counter update flag 720 low. In a second example, the normal control circuit 504 initiates the normal write operation 728 by driving the read strobe 712 low and driving the write strobe 714 high. This causes the column circuit 502 to drive the read/write flag 718 high and drive the array counter update flag 720 low.

The multi-bank control circuit 126 initiates the array counter update procedure 132 based on the external precharge command 522. In particular, the usage-based-disturbance control circuit 510 initiates the usage-based-disturbance read operation 730 by driving the read strobe 712 high and by driving the write strobe 714 low. This causes the column circuit 502 to drive the read/write flag 718 low and drive the array counter update flag 720 high. After the first delay 710-1, the usage-based-disturbance control circuit 510 initiates the usage-based-disturbance write operation 732 by driving the read strobe 712 low and driving the write strobe 714 high. This causes the column circuit 502 to drive the read/write flag 718 high and drive the array counter update flag 720 high. After the second delay 710-2, the activate/precharge circuit 706 initiates the precharge operation 734 by driving the activate/precharge signal 722 low. An example implementation of the usage-based-disturbance control circuit 510 at the local bank level is further described with respect to FIG. 8-1.

FIG. 8-1 illustrates an example local bank control circuit 128 capable of controlling usage-based disturbance mitigation. In the depicted configuration, the local bank control circuit 128 is shown to include the column address strobe circuit 506 (CAS circuit 506), the row address strobe circuit 508 (RAS circuit 508), and the usage-based-disturbance control circuit 510. The usage-based-disturbance control circuit 510 includes the read control circuit 702, the write control circuit 704, and wordline-off circuit 802. The usage-based-disturbance control circuit 510 also includes the delay circuits 708-1 and 708-2. The first delay circuit 708-1 is coupled between the read control circuit 702 and the write control circuit 704. The second delay circuit 708-2 is coupled between the write control circuit 704 and the wordline-off circuit 802.

In this example, the usage-based-disturbance control circuit 510 has a single signal path in which the read control circuit 702, the first delay circuit 708-1, the write control circuit 704, the delay circuit 708-2, and the wordline-off circuit 802 are coupled together in series. Other implementations are also possible. For example, the second delay circuit 708-2 can be coupled between the read control circuit 702 and the wordline-off circuit 802.

Operations of the read control circuit 702, the write control circuit 704, and the delay circuits 708-1 and 708-2 are similar to the operations described above with respect to FIG. 7-1. The column address strobe circuit 506 generates a column address strobe 804 (CAS 804) based on the read strobe 712 and/or the write strobe 714. After the time interval 736 associated with the delays 710-1 and 710-2 has elapsed, the wordline-off circuit 802 generates a wordline-off flag 806 (WL-Off flag 806) to initiate precharging of the activated row. The row address strobe circuit 508 generates a row address strobe 808 (RAS 808) based on the wordline-off flag 806.

The delay circuits 708-1 and 708-2 in FIGS. 7-1 and 8-1 can evaluate elapsed time based on the clock signal 516, based on another timing mechanism that is independent of the clock signal 516, or some combination thereof. In some cases, the first delay circuit 708-1 is implemented using the non-clocked-based timing circuit 514 and uses the timing mechanism that is independent of the clock signal 516, and the second delay circuit 708-2 is implemented using the clocked-based timing circuit 512 and uses the clock signal 516. The delays 710-1 and 710-2 and the time interval 736 can be determined in a manner that provides sufficient margin to account for variations. A timing associated with the signals is further described with respect to FIG. 8-2.

FIG. 8-2 illustrates an example timing diagram 810 for controlling usage-based disturbance mitigation using the local bank control circuit 128. For simplicity, a rising or falling edge of some signals is shown to occur on the dashed line. It is to be understood that there can be an additional delay associated with one or more of these edges that is not explicitly shown in FIG. 8-2. In this example, the memory device 108 performs similar operations as those described with respect to FIG. 7-2.

In the timing diagram 810, the signals represent binary or logic signals. In particular, these signals can have a high voltage, which may be approximately equal to a supply voltage, or a low voltage, which can be approximately equal to a reference voltage. In the example described below, the activate/precharge signal 722 has a low voltage to enable precharging or a high voltage to enable activation. The wordline-off flag 806 can have a low voltage to enable precharging or a high voltage to disable precharging.

Prior to the normal read operation 726 or the normal write operation 728, the multi-bank control circuit 126 initiates activation of a row by driving the activate/precharge signal 722 from low to high. The activate/precharge signal 722 causes the wordline-off circuit 802 to drive the wordline-off flag 806 high. The wordline-off circuit 802 keeps driving the wordline-off flag 806 high for a duration of the normal read operation 726, the normal write operation 728, and the array counter update procedure 132.

The local bank control circuit 128 initiates the array counter update procedure 132 based on the internal precharge command 526. To generate the internal precharge command 526, the multi-bank control circuit 126 drives the activate/precharge signal 722 low. Based on the internal precharge command 526, the usage-based-disturbance control circuit 510 initiates the usage-based-disturbance read operation 730 by driving the read strobe 712 high and by driving the write strobe 714 low. This causes the column address strobe circuit 506 to generate the column address strobe 804 in a manner that enables the usage-based disturbance circuitry 120 to read the activation count. After the first delay 710-1, the usage-based-disturbance control circuit 510 initiates the usage-based-disturbance write operation 732 by driving the read strobe 712 low and driving the write strobe 714 high. This causes the column address strobe circuit 506 to generate the column address strobe 804 in a manner that enables the usage-based disturbance circuitry 120 to write the updated activation count. After the second delay 710-2, the wordline-off circuit 802 initiates the precharge operation 734 by driving the wordline-off flag 806 low. This causes the row address strobe circuit 508 to generate the row address strobe 808 in a manner that causes the activated row to be precharged.

### Example Methods

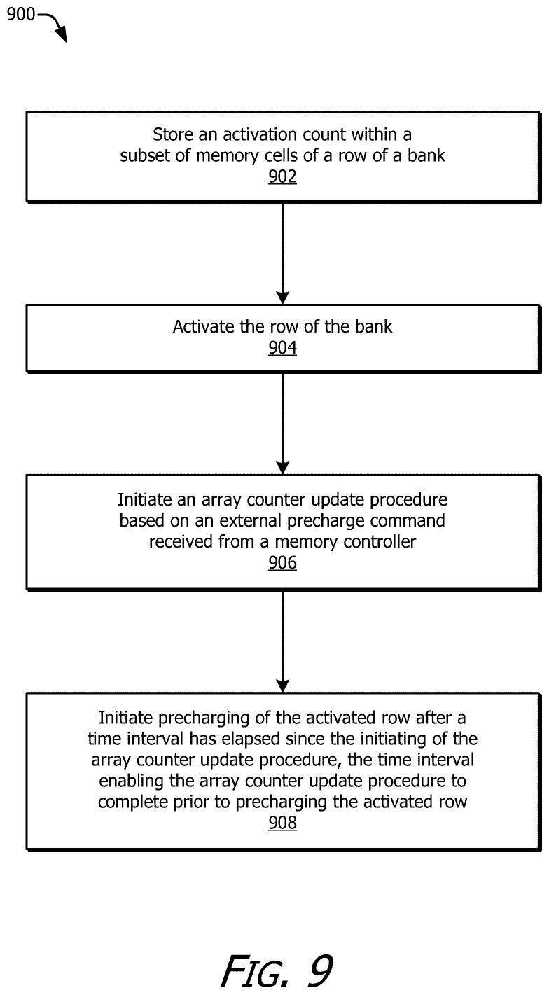

This section describes example methods for implementing aspects of controlling usage-based disturbance mitigation with reference to the flow diagrams of FIGS. 9 to 11. These descriptions may also refer to components, entities, and other aspects depicted in FIGS. 1 to 8-2 by way of example only. The described methods are not necessarily limited to performance by one entity or multiple entities operating on one device.

FIG. 9 illustrates a method 900, which includes operations 902 through 908. In aspects, operations of the method 900 are implemented by a memory device 108 as described with reference to FIG. 1. At 902, an activation count within a subset of memory cells of a row of a bank is stored. For example, a subset of memory cells within a row of a bank 310 stores an activation count, which represents usage-based disturbance data 214 shown in FIG. 2.

At 904, the row of the bank is activated. For example, the control circuitry 122 activates the row of the bank 310. The control circuitry 122 can activate the row based on an external activate command received from the memory controller 114.

At 906, an array counter update procedure is initiated based on an external precharge command that is received from a memory controller. For example, the control circuitry 122 initiates an array counter update procedure 132 based on an external precharge command 522 that is received from the memory controller 114.

At 908, precharging of the activated row is initiated after a time interval has elapsed since the initiating of the array counter update procedure. The time interval enables the array counter update procedure to complete prior to precharging of the activated row. For example, the control circuitry 122 initiates precharging of the activated row after a time interval has elapsed since initiating of the array counter update procedure 132. The time interval enables the usage-based disturbance circuitry 120 to complete the array counter update procedure 132 prior to the activated row being precharged.

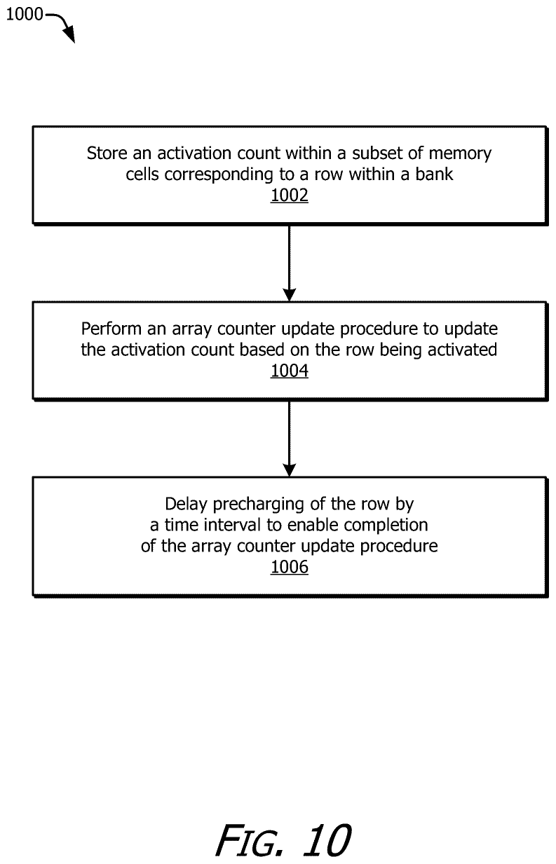

FIG. 10 illustrates a method 1000, which includes operations 1002 through 1006. In aspects, operations of the method 1000 are implemented by a memory device 108 as described with reference to FIG. 1. At 1002, an activation count is stored within a subset of memory cells corresponding to a row within a bank. For example, a subset of memory cells within a row of a bank 310 stores an activation count, which represents usage-based disturbance data 214 shown in FIG. 2.

At 1004, an array counter update procedure is performed to update the activation count based on the row being activated. For example, the usage-based disturbance circuitry 120 performs the array counter update procedure 132 to update the activation count based on the row being activated. More specifically, the usage-based disturbance circuitry 120 reads the activation count from the activated row, updates this activation count (e.g., increments this activation count), and writes the updated activation count to the subset of memory cells.

At 1006, precharging of the row is delayed by a time interval to enable completion of the array counter update procedure. For example, the control circuitry 122 delays, at a multi-bank level or a local bank level, precharging of the row by the time interval to enable the usage-based disturbance circuitry 120 to complete the array counter update procedure 132. Example delays 710-1 and 710-2 are shown in FIGS. 7-2 and 8-2.

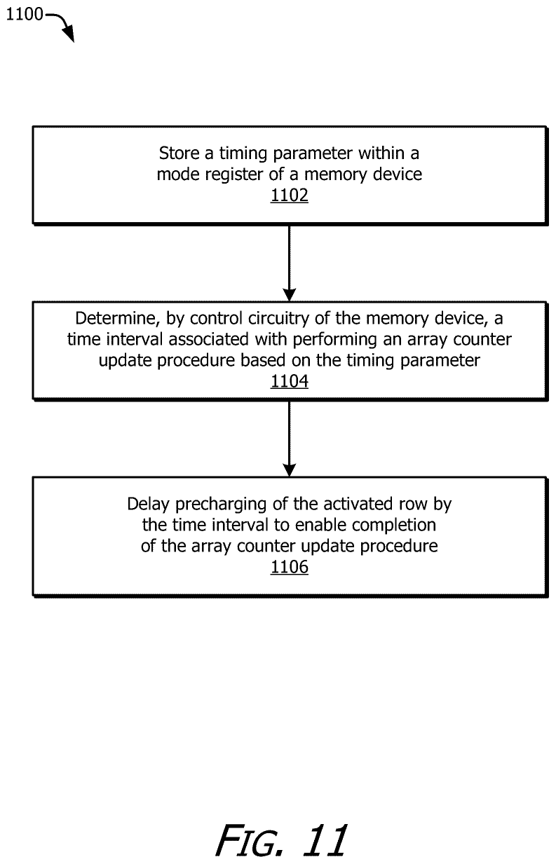

FIG. 11 illustrates a method 1100, which includes operations 1102 through 1106. In aspects, operations of the method 1100 are implemented by a memory device 108 as described with reference to FIG. 1. At 1102, a timing parameter is stored within a mode register of a memory device. For example, the mode register 124 of the memory device 108 stores the timing parameter 130, as shown in FIG. 1. The timing parameter 130 can be stored by a shared operand 604, a usage-based-disturbance-dedicated operand 606, or a non-usage-based-disturbance operand 608, as shown in FIG. 6.

At 1104, a time interval associated with performing an array counter update procedure is determined by control circuitry of the memory device based on the timing parameter. For example, the control circuitry 122 determines the time interval based on the timing parameter 130. In some examples, the timing parameter 130 can directly specify the time interval directly using the shared operand 604 or the usage-based-disturbance-dedicated operand 606. In other examples, the timing parameter 130 can be calculated based on timing parameter 130. For instance, the timing parameter 130 can represent a speed of the host device 104 and the control circuitry 122 can determine the time interval based on the speed of the host device 104.

At 1106, precharging of the activated row is delayed by the time interval to enable completion of the array counter update procedure. For example, the control circuitry 122 delays, at a multi-bank level or a local bank level, precharging of the activated row by the time interval to enable the usage-based disturbance circuitry 120 to complete the array counter update procedure 132. Example delays 710-1 and 710-2 are shown in FIGS. 7-2 and 8-2.

For the figures described above, the orders in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-circuit circuitry or a processor in conjunction with a memory), firmware, software, or some combination thereof. The methods may be realized using one or more of the apparatuses or components shown in FIGS. 1 to 8-2, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of controlling usage-based disturbance mitigation are described:

Example 1: An apparatus comprising:
a memory device comprising:
   at least one bank comprising multiple rows of memory cells, each row of the multiple rows configured to store an activation count within a subset of the memory cells;
   circuitry configured to perform an array counter update procedure to update the activation count corresponding to an activated row within the at least one bank; and
   control circuitry configured to:
      receive an external precharge command from a memory controller; and
      initiate precharging of the activated row after a time interval has elapsed since the receiving of the external precharge command, the time interval being sufficient to enable the array counter update procedure to complete prior to initiating the precharging of the activated row.

Example 2: The apparatus of example 1 or any other example, wherein the control circuitry is configured to:
initiate reading of the activation count within the activated row based on the receiving of the external precharge command; and
initiate writing of the updated activation count within the activated row based on a portion of the time interval elapsing since the initiating of the reading of the activation count; and
initiate the precharging of the activate row based on a remaining portion of the time interval elapsing since the initiating of the writing of the updated activation count.

Example 3: The apparatus of example 1 or any other example, wherein the control circuitry is configured to determine that the time interval has elapsed based on a clock signal.

Example 4: The apparatus of example 1 or any other example, wherein the control circuitry is configured to determine that the time interval has elapsed based on a delay that is independent of a clock signal.

Example 5: The apparatus of example 1 or any other example, wherein the control circuitry comprises:
at least one local bank control circuit coupled to the at least one bank; and
a multi-bank control circuit coupled to the at least one local bank control circuit and configured to initiate the precharging of the activated row after the time interval has elapsed.

Example 6: The apparatus of example 5 or any other example, wherein the multi-bank control circuit is configured to generate a flag that causes the at least one local bank control circuit to perform an operation associated with the array counter update procedure.

Example 7: The apparatus of example 5 or any other example, wherein:
the multi-bank control circuit comprises:
   a column circuit; and
   a control circuit configured to initiate the array counter update procedure and initiate the precharging of the activated row, the control circuit comprising:
      a read control circuit coupled to an input of the column circuit and configured to initiate reading of the activation count as part of the array counter update procedure;
      a write control circuit coupled to another input of the column circuit, the write control circuit configured to initiate writing of an updated activation count as part of the array counter update procedure;
      a first delay circuit coupled between the read control circuit and the write control circuit, the first delay circuit configured to delay the writing of the updated activation count by a first portion of the time interval to enable the reading of the activation count to complete prior to the writing of the updated activation count; and
      a second delay circuit coupled to the write control circuit and configured to delay the precharging of the activated row by a remaining portion of the time interval to enable the writing of the updated activation count to complete prior to the precharging of the activated row.

Example 8: The apparatus of example 7 or any other example, wherein the first and second delay circuits can each comprise one of the following:
a clock-based timing circuit configured to determine that an amount of time has elapsed based on a clock signal; or
another timing circuit configured to determine that the amount of time has elapsed based on a delay that is independent of the clock signal.

Example 9: The apparatus of example 8 or any other example, wherein:
the first delay circuit comprises the other timing circuit; and
the second delay circuit comprises the clock-based timing circuit.

Example 10: The apparatus of example 5 or any other example, wherein a distance between the at least one local bank control circuit and the at least one bank is shorter than a distance between the multi-bank control circuit and the at least one bank.

Example 11: The apparatus of example 5 or any other example, wherein:
the memory device comprises a command decoder; and
the multi-bank control circuit is positioned proximate to the command decoder such that a distance between the multi-bank control circuit and the command decoder is shorter than a distance between the multi-bank control circuit and the at least one bank.

Example 12: The apparatus of example 5 or any other example, wherein:
the control circuitry comprises clock circuitry; and
the multi-bank control circuit is positioned proximate to the clock circuitry such that a distance between the multi-bank control circuit and the clock circuitry is shorter than a distance between the at least one local bank control circuit and the clock circuitry.

Example 13: The apparatus of example 5 or any other example, wherein:
the at least one bank comprises a first bank and a second bank;
the at least one local bank control circuit comprises:
   a first local bank control circuit coupled to the first bank; and
   a second local bank control circuit coupled to the second bank;
the first bank and the first local bank control circuit are positioned on a first side of the multi-bank control circuit; and
the second bank and the second local bank control circuit are positioned on a second side of the multi-bank control circuit that is opposite the first side.

Example 14: The apparatus of example 5 or any other example, wherein:
the at least one bank comprises multiple banks having respective rows that are activated;
the at least one local bank control circuit comprises multiple local bank control circuits respectively coupled to the multiple banks; and
the multi-bank control circuit is coupled to the multiple local bank control circuits and configured to generate multiple flags to cause the local bank control circuits to perform operations associated with the array counter update procedure based on the corresponding rows being activated.

Example 15: The apparatus of example 1 or any other example, wherein the control circuitry comprises:
a multi-bank control circuit configured to:
   receive the external precharge command from the memory controller; and
   generate an internal precharge command based on the external precharge command; and
at least one local bank control circuit coupled to the multi-bank control circuit and the at least one local bank, the at least one local bank control circuit configured to initiate the precharging of the activated row after the time interval has elapsed since the receiving of the internal precharge command.

Example 16: The apparatus of example 15 or any other example, wherein:
the at least one bank comprises multiple banks;
the at least one local bank control circuit comprises multiple local bank control circuits coupled to the multi-bank control circuit and respectively coupled to the multiple banks; and
each of the multiple local bank control circuits comprises control circuit configured to:
   determine that the time interval has elapsed; and
   initiate the precharging of a corresponding activated row based on the determination.

Example 17: The apparatus of example 16 or any other example, wherein:
each of the multiple local bank control circuits comprises:
   a column address strobe circuit configured to generate a column address strobe; and
   a row address strobe circuit configured to generate a row address strobe; and the control circuit comprises:
   a read control circuit coupled to an input of the column address strobe circuit and configured to generate a read strobe;
   a write control circuit coupled to another input of the column address strobe circuit and configured to generate a write strobe;
   a wordline-off circuit coupled to an input of the row address strobe circuit and configured to generate a wordline-off flag;
   a first delay circuit coupled between the read control circuit and the write control circuit; and
   a second delay circuit coupled between the write control circuit and the wordline-off circuit.

Example 18: The apparatus of example 17 or any other example, wherein:
the first delay circuit is configured to determine that a first portion of the time interval has elapsed; and
the second delay circuit is configured to determine that a remaining portion of the time interval has elapsed.

Example 19: The apparatus of example 1 or any other example, wherein:
the control circuitry comprises a mode register configured to store a timing parameter; and
the control circuitry is configured to determine the time interval based on the timing parameter.

Example 20: The apparatus of example 19 or any other example, wherein the timing parameter represents an integer quantity of clock cycles associated with the time interval.

Example 21: The apparatus of example 19 or any other example, wherein:
the mode register comprises a shared operand configured to store the timing parameter; and
the shared operand has a first meaning associated with the timing parameter and a second meaning associated with another parameter of the memory device.

Example 22: The apparatus of example 21 or any other example, wherein the other parameter comprises a write recovery time.

Example 23: The apparatus of example 19 or any other example, wherein:
the memory device is configured to be coupled to a host device; and
the timing parameter represents a speed utilized by the host device.

Example 24: A method performed by a memory device, the method comprising:
storing an activation count within a subset of memory cells of a row of a bank;
activating the row of the bank;
initiating an array counter update procedure based on an external precharge command received from a memory controller; and
initiating precharging of the activated row after a time interval has elapsed since the initiating of the array counter update procedure, the time interval enabling the array counter update procedure to complete prior to precharging the activated row.

Example 25: The method of example 24 or any other example, wherein the initiating of the array counter update procedure comprises:
initiating reading of the activation count within the row based on the receiving of the external precharge command;
initiating writing of the updated activation count within the row based on a first portion of the time interval elapsing since the initiating of the reading of the activation count; and
initiating the precharging of the activated row based on a remaining portion of the time interval elapsing since the initiating of the writing of the updated activation count.

Example 26: The method of example 24 or any other example, wherein:
the initiating of the array counter update procedure comprises generating, by a multi-bank control circuit of the memory device, a flag that causes a local bank control circuit coupled to the bank to perform operations associated with the array counter update procedure; and
the initiating of the precharging comprises determining, by the multi-bank control circuit, that the time interval has elapsed.

Example 27: The method of example 24 or any other example, wherein:
the initiating of the array counter update procedure comprises receiving, by a local bank control circuit of the memory device that is coupled to the bank, an internal precharge command from a multi-bank control circuit of the memory device; and
the initiating the precharging comprises determining, by the local bank control circuit, that the time interval has elapsed.

Example 28: An apparatus comprising:
a memory device comprising:
   multiple banks, each bank of the multiple banks comprising multiple rows of memory cells, each row of the multiple rows configured to store an activation count within a subset of the memory cells;
   circuitry configured to perform an array counter update procedure to update the activation count corresponding to an activated row within a bank of the multiple banks; and
   control circuitry comprising a multi-bank control circuit coupled to the multiple banks and comprising a timing circuit configured to delay precharging of the activated row by a time interval to enable completion of the array counter update procedure.

Example 29: The apparatus of example 28 or any other example, wherein:
the control circuitry comprises multiple local bank control circuits respectively coupled to the multiple banks; and
the multi-bank control circuit is coupled to the multiple local bank control circuits and configured to send, to each of the multiple local bank control circuits, a signal that initiates the array counter update procedure.

Example 30: The apparatus of example 29 or any other example, wherein the multi-bank control circuit is centrally located relative to the multiple local bank control circuits.

Example 31: The apparatus of example 28 or any other example, wherein the timing circuit is configured to determine that the time interval has elapsed based on a delay associated with a first quantity of clock cycles of a clock signal.

Example 32: The apparatus of example 28 or any other example, wherein the timing circuit is configured to determine that the time interval has elapsed based on a delay that is independent of a clock signal.

Example 33: The apparatus of example 28 or any other example, wherein the timing circuit comprises:
a first delay circuit configured to cause a write operation associated with the array counter update procedure to be initiated after a first portion of the time interval has elapsed; and
a second delay circuit configured to cause the precharging of the activated row to be initiated after a remaining portion of the time interval has elapsed.

Example 34: An apparatus comprising:
a memory device comprising:
   multiple banks, each bank of the multiple banks comprising multiple rows of memory cells, each row of the multiple rows configured to store an activation count within a subset of the memory cells;
   circuitry configured to perform an array counter update procedure to update the activation count corresponding to an activated row; and
   control circuitry comprising multiple local bank control circuits respectively coupled to the multiple banks, each of the multiple local bank control circuits comprising a timing circuit configured to delay precharging of the activated row within a corresponding bank by a time interval to enable completion of the array counter update procedure.

Example 35: The apparatus of example 34 or any other example, wherein the timing circuit is configured to:
determine that the time interval has elapsed based on a delay associated with a first quantity of clock cycles of a clock signal; and
initiate precharging of the activated row based on the determination that the timing interval has elapsed.

Example 36: The apparatus of example 34 or any other example, wherein the timing circuit is configured to determine that the time interval has elapsed based on a delay that is independent of a clock signal.

Example 37: The apparatus of example 34 or any other example, wherein the timing circuit comprises:
a first delay circuit configured to cause a write operation associated with the array counter update procedure to be initiated after a first portion of the time interval has elapsed; and
a second delay circuit configured to cause the precharging of the activated row to be initiated after a remaining portion of the time interval has elapsed.

Example 38: A method performed by a memory device, the method comprising:
storing an activation count within a subset of memory cells corresponding to a row within a bank;
preforming an array counter update procedure to update the activation count based on the row being activated; and
delaying precharging of the row by a time interval to enable completion of the array counter update procedure.

Example 39: The method of example 38 or any other example, wherein the delaying of the precharging comprises determining, by a multi-bank control circuit of the memory device, that the time interval has elapsed.

Example 40: The method of example 38 or any other example, wherein the delaying of the precharging comprises determining, by a local bank control circuit of the memory device that is coupled to the bank, that the time interval has elapsed.

Example 41: A method performed by a memory device, the method comprising:
storing a timing parameter within a mode register of the memory device;
determining, by control circuitry of the memory device, a time interval associated with performing an array counter update procedure based on the timing parameter; and
delaying, by the control circuitry, precharging of an activated row by the time interval to enable completion of the array counter update procedure.

Example 42: The method of example 41 or any other example, wherein:
the storing of the timing parameter comprises storing the timing parameter within a shared operand of the mode register; and
the method further comprises specifying, based on a value of the shared operand, a value of another parameter and a value of the timing parameter.

Example 43: The method of example 42 or any other example, wherein the other parameter comprises a write recovery time.

Example 44: The method of example 41 or any other example, wherein:
the storing of the timing parameter comprises storing information associated with a speed utilized by a host device that is coupled to the memory device; and
the method further comprises determining the time interval based on the speed utilized by the host device.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of controlling usage-based disturbance mitigation have been described in language specific to certain features and/or methods, the subject of the appended claims is not necessarily limited to the specific features or methods described. Rather, the specific features and methods are disclosed as a variety of example implementations of controlling usage-based disturbance mitigation.

What is claimed is:

1. An apparatus comprising:
a memory device comprising:
at least one bank comprising multiple rows of memory cells, each row of the multiple rows configured to store an activation count within a subset of the memory cells;
circuitry configured to perform an array counter update procedure to update the activation count corresponding to an activated row within the at least one bank; and
control circuitry configured to:
receive an external precharge command from a memory controller; and
initiate precharging of the activated row after a time interval has elapsed since the receiving of the external precharge command, the time interval being sufficient to enable the array counter update procedure to complete prior to initiating the precharging of the activated row.

2. The apparatus of claim 1, wherein the control circuitry is configured to:
initiate reading of the activation count within the activated row based on the receiving of the external precharge command; and
initiate writing of the updated activation count within the activated row based on a portion of the time interval elapsing since the initiating of the reading of the activation count; and
initiate the precharging of the activate row based on a remaining portion of the time interval elapsing since the initiating of the writing of the updated activation count.

3. The apparatus of claim 1, wherein the control circuitry is configured to determine that the time interval has elapsed based on a clock signal.

4. The apparatus of claim 1, wherein the control circuitry is configured to determine that the time interval has elapsed based on a delay that is independent of a clock signal.

5. The apparatus of claim 1, wherein the control circuitry comprises:
at least one local bank control circuit coupled to the at least one bank; and
a multi-bank control circuit coupled to the at least one local bank control circuit and configured to initiate the precharging of the activated row after the time interval has elapsed.

6. The apparatus of claim 5, wherein the multi-bank control circuit is configured to generate a flag that causes the at least one local bank control circuit to perform an operation associated with the array counter update procedure.

7. The apparatus of claim 5, wherein:
the multi-bank control circuit comprises:
a column circuit; and
a control circuit configured to initiate the array counter update procedure and initiate the precharging of the activated row, the control circuit comprising:
a read control circuit coupled to an input of the column circuit and configured to initiate reading of the activation count as part of the array counter update procedure;
a write control circuit coupled to another input of the column circuit, the write control circuit configured to initiate writing of an updated activation count as part of the array counter update procedure;
a first delay circuit coupled between the read control circuit and the write control circuit, the first delay circuit configured to delay the writing of the updated activation count by a first portion of the time interval to enable the reading of the activation count to complete prior to the writing of the updated activation count; and
a second delay circuit coupled to the write control circuit and configured to delay the precharging of the activated row by a remaining portion of the time interval to enable the writing of the updated activation count to complete prior to the precharging of the activated row.

8. The apparatus of claim 7, wherein the first and second delay circuits can each comprise one of the following:
a clock-based timing circuit configured to determine that an amount of time has elapsed based on a clock signal; or
another timing circuit configured to determine that the amount of time has elapsed based on a delay that is independent of the clock signal.

9. The apparatus of claim 8, wherein:
the first delay circuit comprises the other timing circuit; and
the second delay circuit comprises the clock-based timing circuit.

10. The apparatus of claim 5, wherein a distance between the at least one local bank control circuit and the at least one bank is shorter than a distance between the multi-bank control circuit and the at least one bank.

11. The apparatus of claim 5, wherein:
the memory device comprises a command decoder; and
the multi-bank control circuit is positioned proximate to the command decoder such that a distance between the multi-bank control circuit and the command decoder is shorter than a distance between the multi-bank control circuit and the at least one bank.

12. The apparatus of claim 5, wherein:
the control circuitry comprises clock circuitry; and
the multi-bank control circuit is positioned proximate to the clock circuitry such that a distance between the multi-bank control circuit and the clock circuitry is shorter than a distance between the at least one local bank control circuit and the clock circuitry.

13. The apparatus of claim 5, wherein:
the at least one bank comprises a first bank and a second bank;
the at least one local bank control circuit comprises:
a first local bank control circuit coupled to the first bank; and
a second local bank control circuit coupled to the second bank;
the first bank and the first local bank control circuit are positioned on a first side of the multi-bank control circuit; and
the second bank and the second local bank control circuit are positioned on a second side of the multi-bank control circuit that is opposite the first side.

14. The apparatus of claim 5, wherein:
the at least one bank comprises multiple banks having respective rows that are activated;
the at least one local bank control circuit comprises multiple local bank control circuits respectively coupled to the multiple banks; and
the multi-bank control circuit is coupled to the multiple local bank control circuits and configured to generate multiple flags to cause the local bank control circuits to perform operations associated with the array counter update procedure based on the corresponding rows being activated.

15. The apparatus of claim 1, wherein the control circuitry comprises:
a multi-bank control circuit configured to:
receive the external precharge command from the memory controller; and
generate an internal precharge command based on the external precharge command; and
at least one local bank control circuit coupled to the multi-bank control circuit and the at least one local bank, the at least one local bank control circuit configured to initiate the precharging of the activated row after the time interval has elapsed since the receiving of the internal precharge command.

16. The apparatus of claim 15, wherein:
the at least one bank comprises multiple banks;
the at least one local bank control circuit comprises multiple local bank control circuits coupled to the multi-bank control circuit and respectively coupled to the multiple banks; and
each of the multiple local bank control circuits comprises control circuit configured to:
determine that the time interval has elapsed; and
initiate the precharging of a corresponding activated row based on the determination.

17. The apparatus of claim 16, wherein:
each of the multiple local bank control circuits comprises:
a column address strobe circuit configured to generate a column address strobe; and
a row address strobe circuit configured to generate a row address strobe; and
the control circuit comprises:
a read control circuit coupled to an input of the column address strobe circuit and configured to generate a read strobe;
a write control circuit coupled to another input of the column address strobe circuit and configured to generate a write strobe;
a wordline-off circuit coupled to an input of the row address strobe circuit and configured to generate a wordline-off flag;
a first delay circuit coupled between the read control circuit and the write control circuit; and
a second delay circuit coupled between the write control circuit and the wordline-off circuit.

18. The apparatus of claim 17, wherein:
the first delay circuit is configured to determine that a first portion of the time interval has elapsed; and
the second delay circuit is configured to determine that a remaining portion of the time interval has elapsed.

19. The apparatus of claim 1, wherein:
the control circuitry comprises a mode register configured to store a timing parameter; and
the control circuitry is configured to determine the time interval based on the timing parameter.

20. The apparatus of claim 19, wherein the timing parameter represents an integer quantity of clock cycles associated with the time interval.

21. The apparatus of claim 19, wherein:
the mode register comprises a shared operand configured to store the timing parameter; and
the shared operand has a first meaning associated with the timing parameter and a second meaning associated with another parameter of the memory device.

22. The apparatus of claim 21, wherein the other parameter comprises a write recovery time.

23. The apparatus of claim 19, wherein:
the memory device is configured to be coupled to a host device; and
the timing parameter represents a speed utilized by the host device.

24. A method performed by a memory device, the method comprising:
storing an activation count within a subset of memory cells of a row of a bank;
activating the row of the bank;
initiating an array counter update procedure based on an external precharge command received from a memory controller; and
initiating precharging of the activated row after a time interval has elapsed since the initiating of the array counter update procedure, the time interval enabling the array counter update procedure to complete prior to precharging the activated row.

25. The method of claim 24, wherein the initiating of the array counter update procedure comprises:
initiating reading of the activation count within the row based on the receiving of the external precharge command;
initiating writing of the updated activation count within the row based on a first portion of the time interval elapsing since the initiating of the reading of the activation count; and
initiating the precharging of the activated row based on a remaining portion of the time interval elapsing since the initiating of the writing of the updated activation count.

26. The method of claim 24, wherein:
the initiating of the array counter update procedure comprises generating, by a multi-bank control circuit of the memory device, a flag that causes a local bank control circuit coupled to the bank to perform operations associated with the array counter update procedure; and
the initiating of the precharging comprises determining, by the multi-bank control circuit, that the time interval has elapsed.

27. The method of claim 24, wherein:
the initiating of the array counter update procedure comprises receiving, by a local bank control circuit of the memory device that is coupled to the bank, an internal precharge command from a multi-bank control circuit of the memory device; and
the initiating the precharging comprises determining, by the local bank control circuit, that the time interval has elapsed.

28. An apparatus comprising:
a memory device comprising:
multiple banks, each bank of the multiple banks comprising multiple rows of memory cells, each row of the multiple rows configured to store an activation count within a subset of the memory cells;
circuitry configured to perform an array counter update procedure to update the activation count corresponding to an activated row within a bank of the multiple banks; and
control circuitry comprising a multi-bank control circuit coupled to the multiple banks and comprising a timing circuit configured to delay precharging of the activated row by a time interval to enable completion of the array counter update procedure.

29. The apparatus of claim 28, wherein:
the control circuitry comprises multiple local bank control circuits respectively coupled to the multiple banks; and
the multi-bank control circuit is coupled to the multiple local bank control circuits and configured to send to each of the multiple local bank control circuits, a signal that initiates the array counter update procedure.

30. The apparatus of claim 29, wherein the multi-bank control circuit is centrally located relative to the multiple local bank control circuits.

31. The apparatus of claim 28, wherein the timing circuit is configured to determine that the time interval has elapsed based on a delay associated with a first quantity of clock cycles of a clock signal.

32. The apparatus of claim 28, wherein the timing circuit is configured to determine that the time interval has elapsed based on a delay that is independent of a clock signal.

33. The apparatus of claim 28, wherein the timing circuit comprises:
a first delay circuit configured to cause a write operation associated with the array counter update procedure to be initiated after a first portion of the time interval has elapsed; and
a second delay circuit configured to cause the precharging of the activated row to be initiated after a remaining portion of the time interval has elapsed.

34. An apparatus comprising:
a memory device comprising:
multiple banks, each bank of the multiple banks comprising multiple rows of memory cells, each row of the multiple rows configured to store an activation count within a subset of the memory cells;
circuitry configured to perform an array counter update procedure to update the activation count corresponding to an activated row; and
control circuitry comprising multiple local bank control circuits respectively coupled to the multiple banks, each of the multiple local bank control circuits comprising a timing circuit configured to delay precharging of the activated row within a corresponding bank by a time interval to enable completion of the array counter update procedure.

35. The apparatus of claim 34, wherein the timing circuit is configured to:
determine that the time interval has elapsed based on a delay associated with a first quantity of clock cycles of a clock signal; and
initiate precharging of the activated row based on the determination that the timing interval has elapsed.

36. The apparatus of claim 34, wherein the timing circuit is configured to determine that the time interval has elapsed based on a delay that is independent of a clock signal.

37. The apparatus of claim 34, wherein the timing circuit comprises:
a first delay circuit configured to cause a write operation associated with the array counter update procedure to be initiated after a first portion of the time interval has elapsed; and
a second delay circuit configured to cause the precharging of the activated row to be initiated after a remaining portion of the time interval has elapsed.

38. A method performed by a memory device, the method comprising:
storing an activation count within a subset of memory cells corresponding to a row within a bank;
preforming an array counter update procedure to update the activation count based on the row being activated; and
delaying precharging of the row by a time interval to enable completion of the array counter update procedure.

39. The method of claim 38, wherein the delaying of the precharging comprises determining, by a multi-bank control circuit of the memory device, that the time interval has elapsed.

40. The method of claim 38, wherein the delaying of the precharging comprises determining, by a local bank control circuit of the memory device that is coupled to the bank, that the time interval has elapsed.

41. A method performed by a memory device, the method comprising:
storing a timing parameter within a mode register of the memory device;
determining, by control circuitry of the memory device, a time interval associated with performing an array counter update procedure based on the timing parameter; and
delaying, by the control circuitry, precharging of an activated row by the time interval to enable completion of the array counter update procedure.

42. The method of claim 41, wherein:
the storing of the timing parameter comprises storing the timing parameter within a shared operand of the mode register; and
the method further comprises specifying, based on a value of the shared operand, a value of another parameter and a value of the timing parameter.

43. The method of claim 42, wherein the other parameter comprises a write recovery time.

44. The method of claim 41, wherein:
the storing of the timing parameter comprises storing information associated with a speed utilized by a host device that is coupled to the memory device; and
the method further comprises determining the time interval based on the speed utilized by the host device.
